(19) United States
(12) Patent Application Publication
(10) Pub. No.: US 2025/0391719 A1
(43) Pub. Date: Dec. 25, 2025

(54) Semiconductor Device and Method of Using CTAB to Reduce Occurrence of EM Dendrite Short-Circuit Between Interconnect Structures

(71) Applicant: JCET STATS ChipPAC Korea Limited, Incheon (KR)

(72) Inventors: Minsung Lee, Incheon (KR); Yeojun Yun, Incheon (KR); HeeSoo Lee, Incheon (KR); YoungJo Yoon, Incheon (KR)

(73) Assignee: JCET STATS ChipPAC Korea Limited, Incheon (KR)

(21) Appl. No.: 18/748,143

(22) Filed: Jun. 20, 2024

(51) Int. Cl. H01L 23/29; H01L 21/48; H01L 21/56; H01L 23/00; H01L 23/31; H01L 23/498

(52) U.S. Cl. CPC H01L 23/291; H01L 21/4853; H01L 21/4857; H01L 21/563; H01L 21/565; H01L 23/3128; H01L 23/3135; H01L 23/49822; H01L 24/16; H01L 2224/16225; H01L 2924/0509; H01L 2924/18161; H01L 2924/3841

(57) ABSTRACT

A semiconductor device has a substrate, an electrical component including a plurality of interconnect structures over a first surface of the substrate, and CTAB coating disposed over the plurality of interconnect structures of the electrical component to reduce formation of dendrites between a first one of the plurality of interconnect structures and a second one of plurality of interconnect structures. The electrical component can be a semiconductor die or discrete device. An encapsulant is deposited over the electrical component and substrate. A bump is formed over a second surface of the substrate opposite the first surface of the substrate. CTAB and de-ionized water are dispensed over the electrical component and substrate. The de-ionized water is dried leaving the CTAB coating over the interconnect structures. The CTAB coating completely covers that portion of the interconnect structure exposed between the electrical component and substrate.

### FIELD OF THE INVENTION

The present invention relates in general to semiconductor devices and, more particularly, to a semiconductor device and method of using CTAB to reduce occurrence of EM dendrite-short circuit between interconnect structures.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Multiple semiconductor die and IPDs can be integrated into a system-in-package (SiP) module for higher density in a small space and extended electrical functionality. Within the Sip module, a plurality of semiconductor die and IPDs are disposed on a first surface of a substrate for structural support and electrical interconnect. An encapsulant is deposited over the semiconductor die and IPDs on the first surface of the substrate.

One issue for the electrical component is the possibility of electrochemical migration (EM) from the terminals, e.g., bumps, of the electrical component. FIG. 1a illustrates substrate 50 with adjacent terminal 52 and terminal 54. In FIG. 1b, EM occurs when moisture accumulates between two adjacent terminals 52 and 54 operating under an electrical potential difference, i.e., terminal 52 is negative and terminal 54 is positive. Susceptibility to EM is also affected by electrolyte, bias, temperature, joint geometry, and metal composition. Equations (1) and (2) define the chemical reaction of EM:

$$Sn \to {Sn}^{2 +} + 2 {e}^{-} \qquad ( 1 )$$

$${Sn}^{2 +} \to {Sn}^{4 +} + 2 {e}^{-} \qquad ( 2 )$$

During EM, positive Sn ions 62 dissolve at terminal 54 (anode) and travel towards terminal 52 (cathode) to combine with electrons to form Sn crystals, see FIG. 1c. An electric field is formed between the positive electrodes, see equation (3), and the electric field is formed so that the mobility of electrons is determined according to ion mobility, see equation (4):

$$E = \frac{V}{d} \qquad ( 3 )$$

$$v = uE \qquad ( 4 )$$

where: v is velocity
   u is ion mobility
   E is a magnitude of the field
   D is distance
   V is bias voltage

FIG. 1d shows the growth and formation of Sn dendrites 64 from ions 60 and 62. Equations (5) and (6) define the chemical reaction of the formation of dendrites:

$${Sn}^{4 +} + 4 {e}^{-} \to Sn \qquad ( 5 )$$

$${Sn}^{2 +} + 2 {e}^{-} \to Sn \qquad ( 6 )$$

Sn dendrites 64 create short circuit 66 between terminal 52 and terminal 54. Sn dendrites 64 cause a defect for the semiconductor device, thereby reducing reliability for the semiconductor device, often during otherwise normal operation in the field. EM is particularly problematic with smaller, more densely packaged semiconductor devices.

### BRIEF DESCRIPTION OF THE DRAWINGS

FIGS. 1a-1d illustrate formation of dendrites by EM between two electrical terminals;

FIGS. 2a-2c illustrate a semiconductor wafer with a plurality of semiconductor die separated by a saw street;

FIGS. 3a-3i illustrate a process of forming CTAB coating around the interconnect structures of the electrical component; and

FIG. 4 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

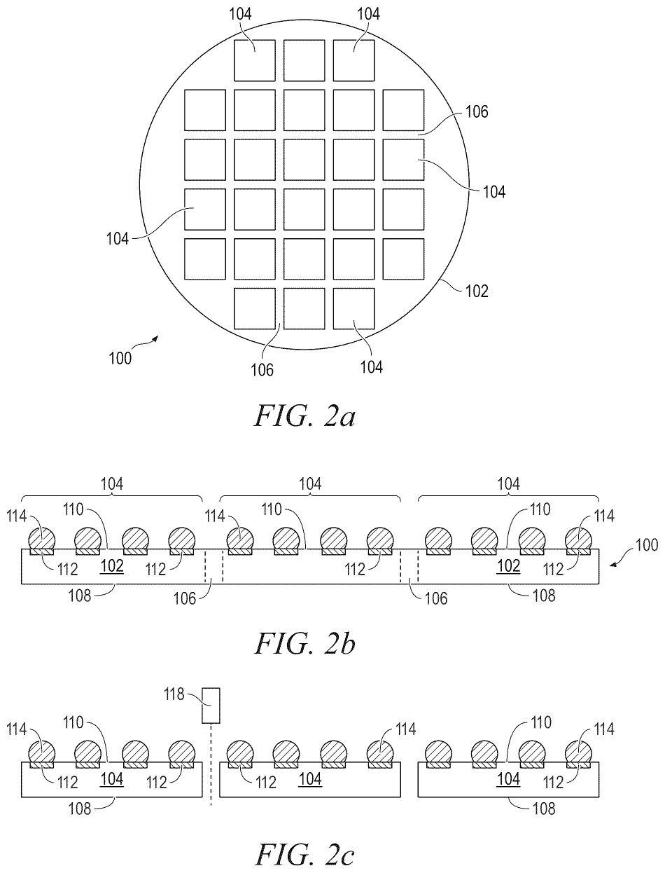

FIG. 2a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 2b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 2c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

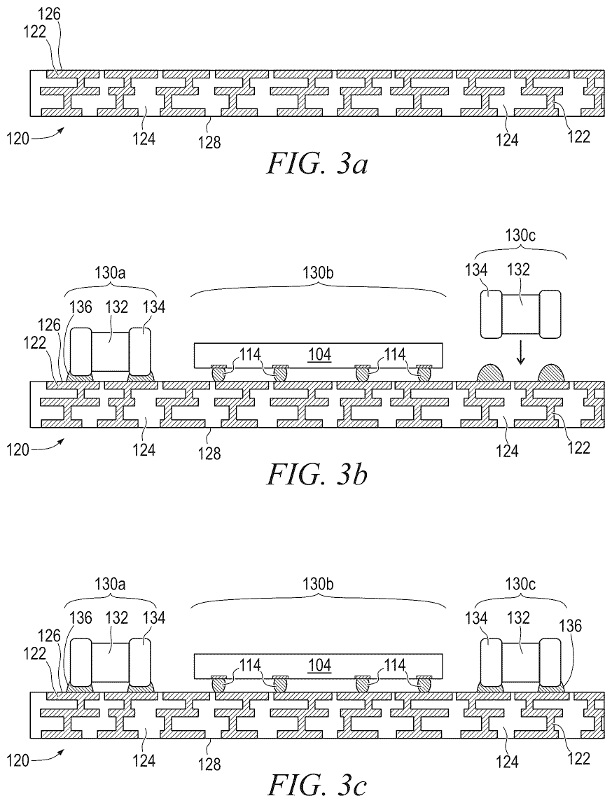

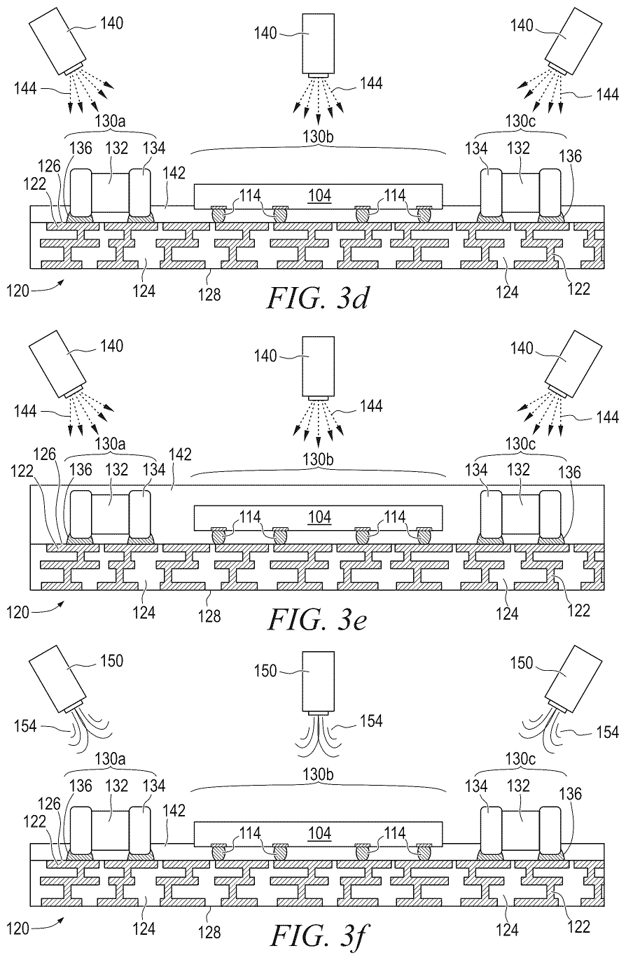

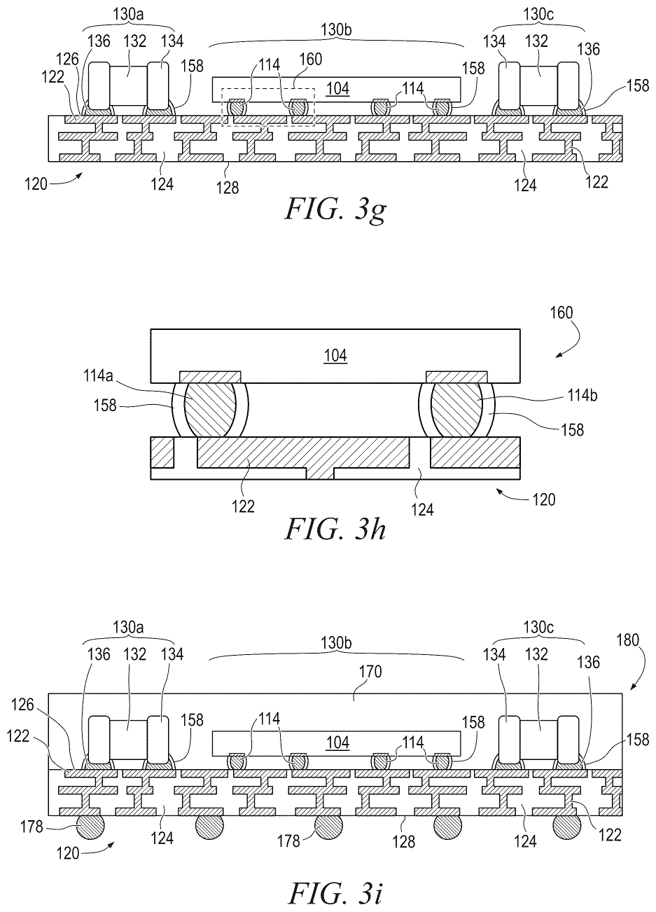

FIGS. 3a-3i illustrate a process of forming CTAB over an interconnect structure of an electrical component to reduce EM dendrite short circuits. FIG. 3a shows a cross-sectional view of interconnect substrate or interposer 120 including one or more conductive layers 122 and one or more insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal electrical interconnect across substrate 120 and vertical electrical interconnect between top surface 126 and bottom surface 128 of substrate 120. Portions of conductive layers 122 can be electrically common or electrically isolated depending on the design and function of semiconductor die 104 and other electrical components. Insulating layers 124 contain one or more layers of silicon dioxide (SiO₂), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 124 can be formed using PVD, CVD, printing, lamination, spin coating, spray coating, sintering or thermal oxidation. Insulating layers 124 provide isolation between conductive layers 122. There can be multiple conductive layers like 122 separated by insulating layers 124.

In FIG. 3b, a plurality of electrical components 130a-130c is disposed on surface 126 of interconnect substrate 120 and electrically and mechanically connected to conductive layers 122. Electrical components 130a-130c are each positioned over substrate 120 using a pick and place operation. For example, electrical component 130a and 130c can be a discrete electrical device 132, or IPD, such as a diode, transistor, resistor, capacitor, and inductor, with terminals 134 disposed on surface 126 of interconnect substrate 120 and electrically and mechanically connected to conductive layers 122 with solder or conductive paste 136. Electrical component 130b can be similar to semiconductor die 104 from FIG. 2c with bumps 114 oriented toward surface 126 of substrate 120. Alternatively, electrical components 130a-130c can include other semiconductor die, semiconductor packages, surface mount devices, discrete electrical devices, interconnect structures, or IPDs.

Electrical components 130a-130c are brought into contact with surface 126 of substrate 120 and bonded to conductive layer 122. FIG. 3c illustrates electrical components 130a-130c electrically and mechanically connected to conductive layers 122 of substrate 120.

In FIG. 3d, a solution 142 of de-ionized water and cetyltrimethylammonium bromide (CTAB) is sprayed over electrical components 130a-130c, as well as surface 126 of substrate 120, using dispensers 140 emitting water jets 144 to cover surface 126 with the solution. In one embodiment, solution 142 is a mixture of de-ionized water and CTAB in the amount of 0.1 grams/liter (g/L). Solution 142 can also be a mixture of various concentrations of de-ionized water and CTAB, such as 0.2, 0.4, and 0.8 g/L, or more generally 0.2-0.8 g/L. In another embodiment, surface 126 can be covered with solution 142 by ultrasonic cleaning or immersion in the solution. In any case, solution 142 of de-ionized water and CTAB covers bumps 114 and conductive paste 136 under electrical components 130a-130c. Dispensers 140 continue to spray water jets 144 until solution 142 covers at least a portion of electrical components 130a-130c. In one embodiment, solution 142 completely covers electrical components 130a-130c, as shown in FIG. 3e. Solution 142 in FIG. 3e is disposed over surface 126 and under electrical components 130a-130c for about 5.0 minutes or greater than 5.0 minutes.

In FIG. 3f, air blowers 150 blow air 154 to dry up solution 142. In one embodiment, air 154 is nitrogen heated to about 100° C., or possible greater than 100° C. FIG. 3f illustrates solution 142 partially dried. FIG. 3g illustrates solution 142 dried over surface 126. However, the application of solution 142 and subsequent drying process has left coating 158 of CTAB covering bumps 114 and conductive paste 136, or at least the portion that is exposed between substrate 120 and electrical components 130a-130c. CTAB coating 158 may still contain some amount of de-ionized water.

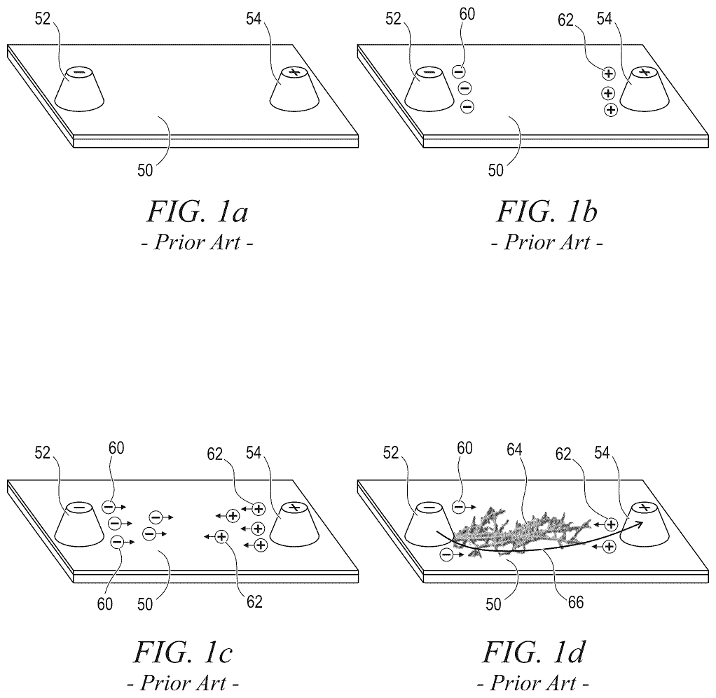

FIG. 3h illustrates further detail of box 160 from FIG. 3g showing, as an example, CTAB coating 158 covering bumps 114. CTAB coating 158 completely covers that portion of bumps 114, conductive paste 136, and any other interconnect structure between electrical components 130a-130c and substrate 120 that is exposed between the electrical component and substrate. Accordingly, coating 158 protects bumps 114, conductive paste 136, and any other interconnect structures of electrical components 130a-130c to reduce or even prevent formation of EM dendrites between adjacent interconnect structures. CTAB coating 158 retards Sn ions from depositing which could form Sn dendrites and thus inhibits Sn-based EM dendrites. With CTAB coating 158, EM dendrites like 66 in FIG. 1d would be unlikely or even highly unlikely to form between bump 114a and bump 114b in FIG. 3h. CTAB coating 158, as disposed over bumps 114, conductive paste 136, and any other interconnect structures of electrical components 130a-130c, has reduced or even prevented formation of EM dendrites between interconnect structures of the electrical components.

In FIG. 3i, an encapsulant or molding compound 170 is deposited over and around electrical components 130a-130c and interconnect substrate 120 using a paste printing, compressive molding, transfer molding, liquid encapsulant molding, vacuum lamination, spin coating, or other suitable applicator. Encapsulant 170 can be polymer composite material, such as epoxy resin with filler, epoxy acrylate with filler, or polymer with proper filler. Encapsulant 170 is non-conductive, provides structural support, and environmentally protects the semiconductor device from external elements and contaminants.

An electrically conductive bump material is deposited over conductive layer 122 on surface 128 of substrate 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 178. In one embodiment, bump 178 is formed over a UBM having a wetting layer, barrier layer, and adhesive layer. Bump 178 can also be compression bonded or thermocompression bonded to conductive layer 122. Bump 178 represents one type of interconnect structure that can be formed over conductive layer 122. The interconnect structure can also use bond wires, conductive paste, stud bump, micro bump, or other electrical interconnect.

The combination of substrate 120, electrical components 130a-130c (with CTAB coating 158), encapsulant 170, and bumps 178 constitutes SiP module 180. Even if EM occurs due to encapsulant delamination after completion of SiP module 180, CTAB coating 158 will reduce or prevent Sn dendrite formation and avoid defects from dendrite-based short circuits between the interconnect structures of the electrical components.

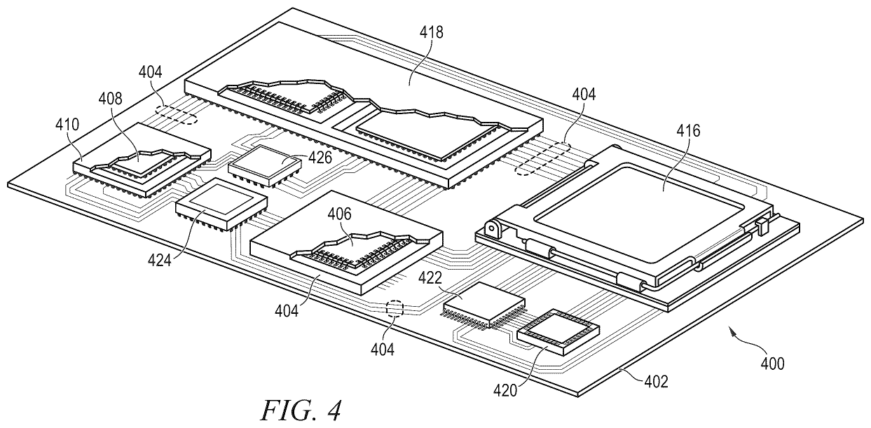

FIG. 4 illustrates electrical device 400 having a chip carrier substrate or PCB 402 with a plurality of semiconductor packages disposed on a surface of PCB 402, including SiP module 180. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 4, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
an electrical component including a plurality of interconnect structures disposed over a first surface of the substrate; and
a cetyltrimethylammonium bromide (CTAB) coating disposed over the plurality of interconnect structures of the electrical component to reduce formation of dendrites between a first one of the plurality of interconnect structures and a second one of plurality of interconnect structures.

2. The semiconductor device of claim 1, further including an encapsulant deposited over the electrical component and substrate.

3. The semiconductor device of claim 1, further including a bump formed over a second surface of the substrate opposite the first surface of the substrate.

4. The semiconductor device of claim 1, wherein the electrical component can be a semiconductor die or discrete device.

5. The semiconductor device of claim 1, wherein the CTAB coating completely covers that portion of the interconnect structure exposed between the electrical component and substrate.

6. The semiconductor device of claim 1, wherein the CTAB coating includes de-ionized water.

7. A semiconductor device, comprising:
an interconnect structure; and
a cetyltrimethylammonium bromide (CTAB) coating disposed over the interconnect structure to reduce formation of dendrites.

8. The semiconductor device of claim 7, further including:
a substrate; and
an electrical component disposed over the substrate, wherein the interconnect structure is disposed between the electrical component and substrate.

9. The semiconductor device of claim 8, further including an encapsulant deposited over the electrical component and substrate.

10. The semiconductor device of claim 7, further including a bump formed over a second surface of the substrate opposite the first surface of the substrate.

11. The semiconductor device of claim 7, wherein the electrical component can be a semiconductor die or discrete device.

12. The semiconductor device of claim 7, wherein the CTAB coating completely covers that portion of the interconnect structure exposed between the electrical component and substrate.

13. The semiconductor device of claim 7, wherein the CTAB coating includes de-ionized water.

14. A method of making a semiconductor device, comprising:
providing a substrate;
disposing an electrical component including a plurality of interconnect structures over a first surface of the substrate; and
disposing a cetyltrimethylammonium bromide (CTAB) coating over the plurality of interconnect structures of the electrical component to reduce formation of dendrites between a first one of the plurality of interconnect structures and a second one of plurality of interconnect structures.

15. The method of claim 14, further including depositing an encapsulant over the electrical component and substrate.

16. The method of claim 14, further including disposing the CTAB coating over the plurality of interconnect structures of the electrical component by dispensing CTAB and de-ionized water over the electrical component and substrate.

17. The method of claim 16, further including disposing the CTAB coating over the plurality of interconnect structures of the electrical component by drying the de-ionized water leaving the CTAB coating over the plurality of interconnect structures of the electrical component.

18. The method of claim 14, wherein the electrical component can be a semiconductor die or discrete device.

19. The method of claim 14, wherein the CTAB coating completely covers that portion of the interconnect structure exposed between the electrical component and substrate.

20. A method of making a semiconductor device, comprising:
providing an interconnect structure; and
disposing a cetyltrimethylammonium bromide (CTAB) coating disposed over the interconnect structure to reduce formation of dendrites.

21. The method of claim 20, further including:
providing a substrate; and
disposing an electrical component over the substrate, wherein the interconnect structure is disposed between the electrical component and substrate.

22. The method of claim 21, further including depositing an encapsulant over the electrical component and substrate.

23. The method of claim 20, further including disposing the CTAB coating over the interconnect structure by dispensing CTAB and de-ionized water over the interconnect structure.

24. The method of claim 23, further including disposing the CTAB coating over the interconnect structure by drying the de-ionized water leaving the CTAB coating over the interconnect structure.

25. The method of claim 20, wherein the CTAB coating completely covers that portion of the interconnect structure exposed between the electrical component and substrate.
